(19) United States
(12) Patent Application Publication
(10) Pub. No.: US 2022/0279284 A1
(43) Pub. Date: Sep. 1, 2022

(54) ELECTROACOUSTIC TRANSDUCER

(71) Applicant: FUJIFILM Corporation, Tokyo (JP)

(72) Inventors: Yusuke KAGAWA, Minamiashigara-shi (JP); Kazuo HIRAGUCHI, Minamiashigara-shi (JP)

(73) Assignee: FUJIFILM Corporation, Tokyo (JP)

(21) Appl. No.: 17/749,371

(22) Filed: May 20, 2022

Related U.S. Application Data
(63) Continuation of application No. PCT/JP2020/040455, filed on Oct. 28, 2020.

(30) Foreign Application Priority Data
Nov. 22, 2019 (JP) 2019-211504

(51) Int. Cl. H04R 17/00; H04R 17/10; H01L 41/047; H01L 41/053

(52) U.S. Cl. CPC H04R 17/005; H04R 17/10; H01L 41/0472; H01L 41/053

(57) ABSTRACT

An object of the present invention is to provide an electroacoustic transducer having a diaphragm and a piezoelectric element, in which the piezoelectric element is replaceable and deterioration of the piezoelectric element caused by moisture absorption can be prevented. The object is accomplished by incorporating a diaphragm, a sealing member affixed to one principal surface of the diaphragm, the sealing member having a gas barrier property and being unsealable and closable after unsealing, and a piezoelectric element sealed in the sealing member and affixed to face the diaphragm in the sealing member, the piezoelectric element using a piezoelectric film provided with electrode layers on both surfaces of a piezoelectric layer.

### CROSS-REFERENCE TO RELATED APPLICATIONS

This application is a Continuation of PCT International Application No. PCT/JP2020/040455 filed on Oct. 28, 2020, which claims priority under 35 U.S.C. § 119(a) to Japanese Patent Application No. 2019-211504 filed on Nov. 22, 2019. The above application is hereby expressly incorporated by reference, in its entirety, into the present application.

### BACKGROUND OF THE INVENTION

### 1. Field of the Invention

The present invention relates to an electroacoustic transducer using a piezoelectric element.

### 2. Description of the Related Art

So-called exciters, which are brought into contact and attached to various articles and vibrate the articles to make a sound, are used in various applications.

For example, in an office, a sound can be produced instead of a speaker by attaching an exciter to a conference table, a whiteboard, a screen, or the like during a presentation, a telephone conference, or the like. In a case of a vehicle such as an automobile, a guide sound, a warning sound, music, or the like can be sounded by attaching an exciter to the console, the A pillar, the roof, or the like. In addition, in a case of an automobile which produces no engine sound, such as a hybrid vehicle and an electric vehicle, a vehicle approach warning sound can be produced from the bumper or the like by attaching an exciter to the bumper or the like.

As a variable element that generates vibration in such an exciter, a combination of a coil and a magnet, a vibration motor such as an eccentric motor and a linear resonance motor, and the like are known.

It is difficult to reduce the thickness of these variable elements. In particular, the vibration motor has disadvantages that, for example, a mass body needs to be increased in order to increase the vibration force, frequency modulation for controlling the degree of vibration is difficult, and a response speed is slow.

On the other hand, in recent years, a speaker is also required to have flexibility in response to, for example, a demand corresponding to a display having flexibility. However, it is difficult to response to a speaker having flexibility with a configuration of the speaker consisting of an exciter and a diaphragm.

It is also considered that a speaker having flexibility is obtained by affixing an exciter having flexibility to a diaphragm having flexibility.

For example, JP4960765B describes a flexible display obtained by integrating a display having flexibility such as an organic electroluminescence display having flexibility and a speaker having flexibility which is formed by interposing a piezoelectric layer (piezoelectric film) such as polyvinylidene fluoride (PVDF) between electrodes. This speaker having flexibility can be positioned as an exciter type speaker that outputs a sound using a piezoelectric element, in which PVDF is interposed between electrodes, as an exciter and a display as a diaphragm.

### SUMMARY OF THE INVENTION

Here, in an exciter type speaker, it is preferable that only an exciter can be replaced in a case where the exciter is in failure.

In addition, a piezoelectric element constituting the exciter has insufficient moisture resistance depending on a material constituting the piezoelectric element, and it is necessary to protect the exciter from moisture absorption.

However, with regard to an electroacoustic transducer such as an exciter type speaker having a diaphragm and a piezoelectric element, an electroacoustic transducer in which an exciter is replaceable and deterioration of the exciter caused by moisture absorption can be prevented has not been realized.

An object of the present invention is to solve such a problem in the related art, and is to provide an electroacoustic transducer having a diaphragm and a piezoelectric element acting as an exciter, in which the piezoelectric element is replaceable and deterioration of the piezoelectric element caused by moisture absorption can be prevented.

In order to accomplish such an object, the present invention has the following configurations.

[1] An electroacoustic transducer comprising:

a diaphragm;

a sealing member affixed to one principal surface of the diaphragm, the sealing member having a gas barrier property and being unsealable and closable after unsealing; and

a piezoelectric element sealed in the sealing member and affixed to face the diaphragm in the sealing member, the piezoelectric element using a piezoelectric film provided with electrode layers on both surfaces of a piezoelectric layer.

[2] The electroacoustic transducer as described in [1],

in which an affixing force between the sealing member and the piezoelectric element is weaker than an affixing force between the diaphragm and the sealing member, or

the affixing force between the sealing member and the piezoelectric element is set to be weaker than the affixing force between the diaphragm and the sealing member.

[3] The electroacoustic transducer as described in [1] or [2],

in which an affixing agent that affixes the piezoelectric element and the sealing member to each other has an affixing force that decreases by moisture absorption.

[4] The electroacoustic transducer as described in any one of [1] to [3],

in which the piezoelectric element has a plurality of layers of the piezoelectric film laminated.

[5] The electroacoustic transducer as described in [4],

in which the piezoelectric element has the plurality of layers of the piezoelectric film laminated by folding the piezoelectric film one or more times.

[6] The electroacoustic transducer as described in any one of [1] to [5],

in which the sealing member is closable by heat-welding after unsealing.

[7] The electroacoustic transducer as described in any one of [1] to [6],

in which the piezoelectric layer of the piezoelectric film is a polymer-based piezoelectric composite material having piezoelectric particles in a polymer material.

[8] The electroacoustic transducer as described in [7],

in which the polymer material has a cyanoethyl group.

[9] The electroacoustic transducer as described in [8],

in which the polymer material is cyanoethylated polyvinyl alcohol.

[10] The electroacoustic transducer as described in any one of [1] to [9],

in which the piezoelectric film has a protective layer on a surface of the electrode layer.

According to the present invention as described above, it is possible to provide an electroacoustic transducer having a diaphragm and a piezoelectric element acting as an exciter, in which the piezoelectric element is replaceable and deterioration of the piezoelectric element caused by moisture absorption can be prevented.

### BRIEF DESCRIPTION OF THE DRAWINGS

FIG. 1 is a view conceptually showing an example of an electroacoustic transducer of an embodiment of the present invention.

FIG. 2 is a view conceptually showing an example of a piezoelectric film constituting a piezoelectric element.

FIG. 3 is a conceptual view for describing an example of a method for manufacturing a piezoelectric film.

FIG. 4 is a conceptual view for describing an example of the method for manufacturing a piezoelectric film.

FIG. 5 is a conceptual view for describing an example of the method for manufacturing a piezoelectric film.

FIG. 6 is a conceptual view showing an action of an electroacoustic transducer.

FIG. 7 is a view conceptually showing another example of the electroacoustic transducer of the embodiment of the present invention.

### DESCRIPTION OF THE PREFERRED EMBODIMENTS

Hereinafter, an electroacoustic transducer of an embodiment of the present invention will be described in detail based on the suitable embodiments shown in the accompanying drawings.

Descriptions on the configuration requirements which will be described later are made based on representative embodiments of the present invention in some cases, but it should not be construed that the present invention is limited to such embodiments.

In addition, the figures shown below are conceptual views for describing the electroacoustic transducer of the embodiment of the present invention, and the size, the thickness, the shape, the positional relationship, and the like of each member are different from the actual values.

Furthermore, in the present specification, the numerical range represented by “to” means a range including numerical values denoted before and after “to” as a lower limit value and an upper limit value, respectively.

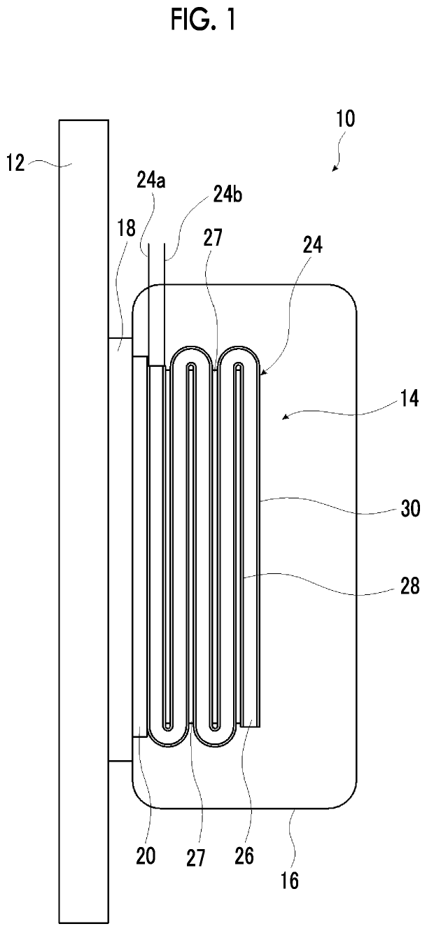

FIG. 1 conceptually shows an example of the electroacoustic transducer of the embodiment of the present invention.

An electroacoustic transducer 10 shown in FIG. 1 has a diaphragm 12, a piezoelectric element 14, and a sealing member 16.

The sealing member 16 is affixed to the diaphragm 12 by an affixing layer 18. The piezoelectric element 14 is sealed by the sealing member 16. The piezoelectric element 14 is affixed to the sealing member 16 at a position facing the diaphragm 12 by an affixing layer 20.

As will be described in detail later, in the electroacoustic transducer 10, the piezoelectric element 14 acts as an exciter that causes the diaphragm 12 to vibrate mentioned above.

That is, in the electroacoustic transducer 10, the piezoelectric element 14 stretches and contracts in the plane direction by applying a driving voltage to the piezoelectric element 14 (the piezoelectric film 24 which will be described later). The stretching and contraction of the piezoelectric element 14 in the plane direction causes the diaphragm 12 to bend, and as a result, the diaphragm 12 vibrates in the thickness direction. The diaphragm 12 generates a sound due to the vibration in the thickness direction. That is, the diaphragm 12 vibrates according to a magnitude of the voltage (driving voltage) applied to the piezoelectric element 14, and generates a sound according to the driving voltage applied to the piezoelectric element 14.

In the electroacoustic transducer 10 of the embodiment of the present invention, the diaphragm 12 is not limited, and various sheet-like objects (plate-like objects, films) which can be used for an exciter-type speaker which outputs a sound by vibration through a so-called exciter are available.

Examples of the diaphragm 12 include resin films consisting of polyethylene terephthalate (PET), polypropylene (PP), polystyrene (PS), polycarbonate (PC), polyphenylene sulfide (PPS), polymethyl methacrylate (PMMA), and polyetherimide (PEI), polyimide (PI), polyethylene naphthalate (PEN), triacetyl cellulose (TAC), a cyclic olefin-based resin, or the like, foamed plastic consisting of foamed polystyrene, foamed styrene, foamed polyethylene, or the like, and various corrugated cardboard materials obtained by bonding other paperboards to one or both surfaces of wavy paperboards.

In addition, in the electroacoustic transducer 10 of the embodiment of the present invention, a display device such as an organic electroluminescence (organic light emitting diode (OLED)) display, a liquid crystal display, a micro light emitting diode (LED) display, and an inorganic electroluminescence display can be suitably used as the diaphragm 12.

The diaphragm 12 may have flexibility.

In the present invention, the expression of having flexibility has the same definition as an expression of having flexibility in general interpretation, and indicates being bendable and being flexible, specifically, being bendable and stretchable without causing breakage and damage.

In the piezoelectric element 14, a piezoelectric film 24 having a first electrode layer 28 on one surface of a piezoelectric layer 26 and a second electrode layer 30 on the other surface is used.

The piezoelectric element 14 in the example illustrated in the figure may have five layers of the piezoelectric film 24 laminated by folding the piezoelectric film 24 four times. In addition, the adjacent layers of the piezoelectric film 24 laminated are affixed to each other by an affixing layer 27.

Furthermore, in the electroacoustic transducer 10 of the embodiment of the present invention, the piezoelectric element 14 is not limited to those having five layers of the piezoelectric film 24 laminated. That is, in the electroacoustic transducer 10 of the embodiment of the present invention, the piezoelectric element 14 may have four or less layers of the piezoelectric film 24 laminated by folding the piezoelectric film 24 three times or less, or may have six or more layers of the piezoelectric film 24 laminated by folding the piezoelectric film 24 five times or more.

As will be described later, by laminating a plurality of layers of the piezoelectric film 24 in this manner, it is possible to bend the diaphragm with a larger force, as compared with a case where one sheet of the piezoelectric film is used. In addition, the electrode can be extracted in one place by the lamination by folding one sheet of the piezoelectric film 24, and the configuration of the electroacoustic transducer 10 can be simplified.

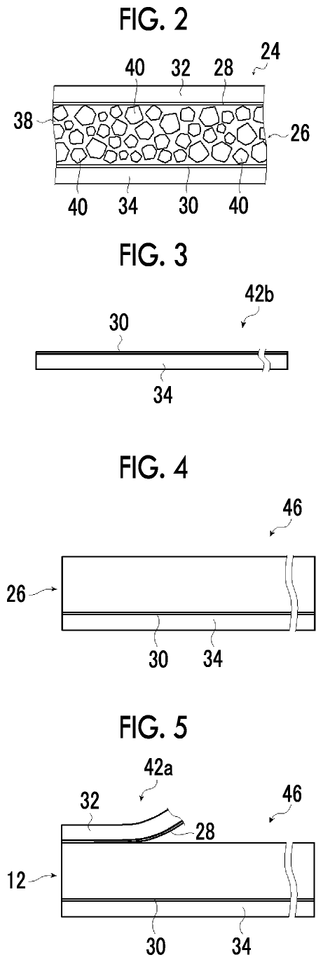

FIG. 2 is a cross-sectional view conceptually showing an example of the piezoelectric film 24. In FIG. 2 and the like, hatching will be omitted in order to clarify the configuration by simplifying the drawing.

Furthermore, in the following description, a “cross section” indicates a cross section of a piezoelectric film in the thickness direction unless otherwise specified. The thickness direction of the piezoelectric film is a lamination direction of each layer.

A piezoelectric film 24 shown in FIG. 2 includes a piezoelectric layer 26, a first electrode layer 28 laminated on one surface of the piezoelectric layer 26, a first protective layer 32 laminated on the first electrode layer 28, a second electrode layer 30 laminated on the other surface of the piezoelectric layer 26, and a second protective layer 34 laminated on the second electrode layer 30.

Furthermore, the first protective layer 32 and the second protective layer 34 of the piezoelectric film 24 are omitted in FIG. 1 in order to clarify the configuration by simplifying the drawing.

In the piezoelectric film 24, various known piezoelectric layers can be used as the piezoelectric layer 26.

In the piezoelectric film 24, as conceptually shown in FIG. 2, the piezoelectric layer 26 is preferably a polymer-based piezoelectric composite material including the piezoelectric particles 40 in the polymer matrix 38 including the polymer material.

Here, it is preferable that the polymer-based piezoelectric composite material (the piezoelectric layer 26) has the following requirements. Further, in the present invention, room temperature is in a range of 0° C. to 50° C.

(i) Flexibility

For example, in a case of being gripped in a state of being loosely bent like a document such as a newspaper and a magazine as a portable device, the piezoelectric film is continuously subjected to large bending deformation from the outside at a relatively slow vibration of less than or equal to a few Hz. In this case, in a case where the polymer-based piezoelectric composite material is hard, a large bending stress is generated to that extent, and a crack is generated at the interface between a polymer matrix and piezoelectric particles, which may lead to breakage. Accordingly, the polymer-based piezoelectric composite material is required to have suitable flexibility. In addition, in a case where strain energy is diffused into the outside as heat, the stress is able to be relieved. Accordingly, a loss tangent of the polymer-based piezoelectric composite material is required to be suitably large.

(ii) Acoustic Quality

In a speaker, the piezoelectric particles vibrate at a frequency of an audio band of 20 Hz to 20 kHz, and the vibration energy causes the entire diaphragm (polymer-based piezoelectric composite material) to vibrate integrally so that a sound is reproduced. Accordingly, in order to increase the transmission efficiency of the vibration energy, the polymer-based piezoelectric composite material is required to have an appropriate hardness. In addition, in a case where the frequency characteristics of the speaker are smooth, an amount of change in acoustic quality in a case where the lowest resonance frequency f₀ is changed in association with a change in the curvature of the speaker decreases. Accordingly, the loss tangent of the polymer-based piezoelectric composite material is required to be suitably large.

It is known that the lowest resonance frequency f₀ of the diaphragm for a speaker is represented by the following equation. Here, s represents the stiffness of the vibration system and m represents the mass.

$$Lowest resonance frequency : {f}_{0} = \frac{1}{2 π} \sqrt{\frac{s}{m}} \qquad [ Equation 1 ]$$

Here, as a degree of curvature of the piezoelectric film, that is, a radius of curvature of the curved part increases, a mechanical stiffness decreases, whereby a lowest resonance frequency f₀ decreases. That is, an acoustic quality (a volume and frequency characteristics) of the speaker changes depending on the radius of curvature of the piezoelectric film.

That is, the polymer-based piezoelectric composite material is required to exhibit a behavior of being rigid with respect to a vibration at 20 Hz to 20 kHz and being flexible with respect to a vibration of less than or equal to a few Hz. In addition, the loss tangent of a polymer-based piezoelectric composite material is required to be suitably large with respect to a vibration at all frequencies of 20 kHz or less.

In general, a polymer solid has viscoelasticity relieving mechanism, and molecular movement having a large scale is observed as a decrease (relief) in a storage elastic modulus (Young's modulus) or a maximal value (absorption) in a loss elastic modulus along with an increase in a temperature or a decrease in a frequency. Among these, the relief due to a micro-brownian motion of a molecular chain in an amorphous region is referred to as main dispersion, and an extremely large relieving phenomenon is observed. A temperature at which this main dispersion occurs is a glass transition point Tg, and the viscoelasticity relieving mechanism is most remarkably observed.

In the polymer-based piezoelectric composite material (piezoelectric layer 26), the polymer-based piezoelectric composite material exhibiting a behavior of being rigid with respect to a vibration of 20 Hz to 20 kHz and being flexible with respect to a vibration of less than or equal to a few Hz is realized by using a polymer material whose glass transition point is room temperature, that is, a polymer material having a viscoelasticity at room temperature as a matrix. In particular, from the viewpoint that such a behavior is suitably exhibited, it is preferable that the polymer material in which the glass transition point Tg at a frequency of 1 Hz is at room temperature is used for a matrix of the polymer-based piezoelectric composite material.

In the polymer material serving as a polymer matrix 38, it is preferable that the maximal value of a loss tangent tans at a frequency of 1 Hz according to a dynamic viscoelasticity test at room temperature is 0.5 or more.

In this manner, in a case where the polymer-based piezoelectric composite material is slowly bent due to an external force, stress concentration on the interface between the polymer matrix and the piezoelectric particles at most bending moment portion is relieved, and thus, satisfactory flexibility can be expected.

In addition, in the polymer material serving as the polymer matrix 38, it is preferable that a storage elastic modulus (E′) at a frequency of 1 Hz according to the dynamic viscoelasticity measurement is 100 MPa or more at 0° C. and 10 MPa or less at 50° C.

In this manner, it is possible to reduce a bending moment which is generated in a case where the polymer-based piezoelectric composite material is slowly bent due to the external force, and it is also possible to make the polymer-based piezoelectric composite material rigid with respect to an acoustic vibration of 20 Hz to 20 kHz.

In addition, it is more suitable that the relative dielectric constant of the polymer material serving as the polymer matrix 38 is 10 or more at 25° C. In this manner, in a case where a voltage is applied to the polymer-based piezoelectric composite material, a higher electric field is applied to the piezoelectric particles in the polymer matrix, whereby a large deformation amount can be expected.

However, in consideration of securing good moisture resistance, or the like, it is suitable that the relative permittivity of the polymer material is 10 or less at 25° C.

Suitable examples of the polymer material that satisfies such conditions include cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, and polybutyl methacrylate.

In addition, as these polymer materials, a commercially available product such as HYBRAR 5127 (manufactured by Kuraray Co., Ltd.) can be suitably used.

Among these, it is preferable to use a polymer material having a cyanoethyl group and particularly preferable to use cyanoethylated PVA as the polymer material constituting the polymer matrix 38. That is, in the piezoelectric film 24, it is preferable to use a polymer material having a cyanoethyl group and particularly preferable to use cyanoethylated PVA as the polymer matrix 38 of the piezoelectric layer 26.

In the following description, the above-described polymer materials typified by cyanoethylated PVA will also be collectively referred to as the “polymer material having a viscoelasticity at room temperature”.

Furthermore, the polymer material having a viscoelasticity at room temperature may be used alone or in combination of two or more kinds thereof (mixture).

In the piezoelectric film 24, a plurality of polymer materials may be used in combination, as necessary, for the polymer matrix 38 of the piezoelectric layer 26.

That is, for the purpose of adjusting dielectric characteristics, mechanical characteristics, and the like, other dielectric polymer materials may be added to the polymer matrix 38 constituting the polymer-based piezoelectric composite material in addition to the polymer material having a viscoelasticity at room temperature, as necessary.

Examples of the dielectric polymer material that can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among those, the polymer material having a cyanoethyl group is suitably used.

In addition, in the polymer matrix 38 of the piezoelectric layer 26, the number of these dielectric polymer materials is not limited to one, and a plurality of kinds of dielectric polymer materials may be added.

In addition, for the purpose of adjusting the glass transition point Tg of the polymer matrix 38, a thermoplastic resin such as a vinyl chloride resin, polyethylene, polystyrene, a methacrylic resin, polybutene, or isobutylene, and a thermosetting resin such as a phenol resin, a urea resin, a melamine resin, an alkyd resin, or mica may also be added, in addition to the dielectric polymer materials.

Furthermore, for the purpose of improving the pressure sensitive adhesiveness, a viscosity imparting agent such as rosin ester, rosin, terpene, terpene phenol, and a petroleum resin may be added.

In the polymer matrix 38 of the piezoelectric layer 26, the addition amount in a case of adding polymer materials other than the polymer material having a viscoelasticity at room temperature is not particularly limited, but is preferably set to 30% by mass or less in terms of a proportion of the polymer materials in the polymer matrix 38.

In this manner, the characteristics of the polymer material to be added can be exhibited without impairing the viscoelasticity relieving mechanism in the polymer matrix 38, whereby preferred results, for example, an increase in a dielectric constant, improvement of heat resistance, and improvement of adhesiveness between the piezoelectric particles 40 and the electrode layer can be obtained.

The polymer-based piezoelectric composite material serving as the piezoelectric layer 26 includes the piezoelectric particles 40 in the polymer matrix. The piezoelectric particles 40 are dispersed in a polymer matrix, and preferably uniformly (substantially uniformly) dispersed therein.

It is preferable that the piezoelectric particles 40 consist of ceramic particles having a perovskite type or wurtzite type crystal structure.

Examples of the ceramics particles constituting the piezoelectric particles 40 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

The particle diameters of the piezoelectric particles 40 may be appropriately selected according to the size, the application, and the like of the piezoelectric film 24. The particle diameters of the piezoelectric particles 40 are preferably 1 to 10 μm.

By setting the particle diameters of the piezoelectric particles 40 to be in the range, preferred results from the viewpoints of achieving both excellent piezoelectric characteristics and flexibility, and the like can be obtained.

In the piezoelectric film 24, a ratio between the amount of the polymer matrix 38 and the amount of the piezoelectric particles 40 in the piezoelectric layer 26 may be appropriately set according to the size and the thickness of the piezoelectric film 24 in the plane direction, the application of the piezoelectric film 24, the characteristics required for the piezoelectric film 24, and the like.

A volume fraction of the piezoelectric particles 40 in the piezoelectric layer 26 is preferably in a range of 30% to 80%, and more preferably in a range of 50% to 80%.

By setting the ratio between the amount of the polymer matrix 38 and the amount of the piezoelectric particles 40 to be in the range, preferred results from the viewpoints of achieving both excellent piezoelectric characteristics and flexibility, and the like can be obtained.

In the piezoelectric film 24, a thickness of the piezoelectric layer 26 is not limited and may be appropriately set according to the size of the piezoelectric film 24, the application of the piezoelectric film 24, the characteristics required for the piezoelectric film 24, and the like.

The thickness of the piezoelectric layer 26 is preferably 8 to 300 μm, more preferably 8 to 200 μm, still more preferably 10 to 150 μm, and particularly preferably 15 to 100 μm.

By setting the thickness of the piezoelectric layer 26 to be in the range, it is possible to obtain preferred results from the viewpoints of achieving both ensuring of the rigidity and appropriate flexibility, and the like.

It is preferable that the piezoelectric layer 26 is subjected to a polarization treatment (poling) in the thickness direction. The polarization treatment will be described in detail later.

Moreover, in the piezoelectric film 24, the piezoelectric layer 26 is not limited to the polymer-based piezoelectric composite material including the piezoelectric particles 40 in the polymer matrix 38 consisting of a polymer material having viscoelasticity at room temperature, such as cyanoethylated PVA, as described above.

That is, in the piezoelectric film 24, various known piezoelectric layers can be used as the piezoelectric layer.

By way of an example, a polymer-based piezoelectric composite material including the same piezoelectric particles 40 in a matrix including a dielectric polymer material such as polyvinylidene fluoride, a vinylidene fluoride-tetrafluoroethylene copolymer, and a vinylidene fluoride-trifluoroethylene copolymer mentioned above, a piezoelectric layer consisting of polyvinylidene fluoride, a piezoelectric layer consisting of a fluororesin other than polyvinylidene fluoride, a piezoelectric layer obtained by laminating a film consisting of poly-L lactic acid and a film consisting of poly-D lactic acid, and the like are also available.

However, from the viewpoint that the polymer-based piezoelectric composite material can behave hard for vibrations at 20 Hz to 20 kHz and behave softly for slow vibrations at several Hz or less as described above, and can have excellent acoustic characteristics, excellent flexibility, and the like, a polymer-based piezoelectric composite material including the piezoelectric particles 40 in the polymer matrix 38 consisting of a polymer material having viscoelasticity at room temperature, such as the above-mentioned cyanoethylated PVA, is suitably used.

The piezoelectric film 24 shown in FIG. 2 has a configuration to have a second electrode layer 30 on one surface of such a piezoelectric layer 26, a second protective layer 34 on a surface of the second electrode layer 30, a first electrode layer 28 on the other surface of the piezoelectric layer 26, and a first protective layer 32 on a surface of the first electrode layer 28. In the piezoelectric film 24, the first electrode layer 28 and the second electrode layer 30 form an electrode pair.

In other words, the laminated film constituting the piezoelectric film 24 has a configuration in which both surfaces of the piezoelectric layer 26 are interposed between electrode pairs, that is, the first electrode layer 28 and the second electrode layer 30, and further interposed between the first protective layer 32 and the second protective layers 34.

In this manner, the region interposed between the first electrode layer 28 and the second electrode layer 30 is driven according to the applied voltage.

In the present invention, the first and second electrodes in the first electrode layer 28, the second electrode layer 30, and the like are added for convenience in order to describe the piezoelectric film 24.

Therefore, “first” and “second” in the piezoelectric film 24 have no technical meanings and are irrelevant to the actual usage state.

The piezoelectric film 24 may have, in addition to those layers, for example, an affixing layer for affixing the electrode layer and the piezoelectric layer 26 to each other, and/or an affixing layer for affixing the electrode layer and the protective layer to each other.

The affixing agent may be an adhesive or a pressure sensitive adhesive. In addition, the same material as the polymer material obtained by removing the piezoelectric particles 40 from the piezoelectric layer 26, that is, the polymer matrix 38 can also be suitably used as the affixing agent. Furthermore, the affixing layer may be provided on both the first electrode layer 28 side and the second electrode layer 30 side, or may also be provided on only one of the first electrode layer 28 side and the second electrode layer 30 side.

In the piezoelectric film 24, the first protective layer 32 and the second protective layer 34 play a role to impart moderate rigidity and mechanical strength to the piezoelectric layer 26 while covering the first electrode layer 28 and the second electrode layer 30. That is, in the piezoelectric film 24, the piezoelectric layer 26 including the polymer matrix 38 and the piezoelectric particles 40 exhibits extremely excellent flexibility for bending deformation at a slow vibration, whereas it may have insufficient rigidity, mechanical strength, and the like depending on the applications. As a compensation for this, the piezoelectric film 24 is provided with the first protective layer 32 and the second protective layer 34.

The first protective layer 32 and the second protective layer 34 have the same configuration despite of different disposition positions. Accordingly, in the following description, in a case where it is not necessary to distinguish the first protective layer 32 from the second protective layer 34, both members are collectively referred to as a protective layer.

The protective layer is not limited, various sheet-like materials can be used as the protective layer, and suitable examples thereof include various resin films. Among these, from the viewpoints of excellent mechanical characteristics and heat resistance, a resin film consisting of polyethylene terephthalate (PET), polypropylene (PP), polystyrene (PS), polycarbonate (PC), polyphenylene sulfide (PPS), polymethyl methacrylate (PMMA), polyetherimide (PEI), polyimide (PI), polyamide (PA), polyethylene naphthalate (PEN), triacetyl cellulose (TAC), and a cyclic olefin-based resin is suitably used.

A thickness of the protective layer is not limited. In addition, the thicknesses of the first protective layer 32 and the second protective layer 34 are basically the same as each other, but may be different from each other.

Here, in a case where the rigidity of the protective layer is extremely high, not only is the stretching and contraction of the piezoelectric layer 26 constrained, but also the flexibility is impaired. Therefore, it is advantageous that the thickness of the protective layer decreases, except for a case where the mechanical strength, and excellent handleability and the like for a sheet-like material are required.

In a case where the thickness of the first protective layer 32 and the thickness of the second protective layer 34 are each twice or less the thickness of the piezoelectric layer 26, preferred results from the viewpoints of achieving both ensuring of the rigidity and moderate flexibility, and the like can be obtained.

For example, in a case where the thickness of the piezoelectric layer 26 is 50 μm, and the first protective layer 32 and the second protective layer 34 consist of PET, the thickness of the first protective layer 32 and the thickness of the second protective layer 34 are each preferably 100 μm or less, more preferably 50 gm or less, and still more preferably 25 gm or less.

Moreover, in the present invention, the first protective layer 32 and the second protective layer 34 are provided in a preferred aspect, and are not an essential configuration requirement. That is, in the electroacoustic transducer of the embodiment of the present invention, the piezoelectric film may have only the first protective layer 32 or only the second protective layer 34, or may also have neither of the first protective layer 32 nor the second protective layer 34. However, in consideration of the strength, handleability, protection of the electrode layer, and the like of the piezoelectric film 24, it is preferable that the piezoelectric film has both the first protective layer 32 and the second protective layer 34 as shown in the example illustrated in the figure.

In the piezoelectric film 24, the first electrode layer 28 is formed between the piezoelectric layer 26 and the first protective layer 32, and the second electrode layer 30 is formed between the piezoelectric layer 26 and the second protective layer 34. The first electrode layer 28 and the second electrode layer 30 are provided to apply an electric field to the piezoelectric film 24 (piezoelectric layer 26).

The first electrode layer 28 and the second electrode layer 30 are basically the same, except that the positions are different. Accordingly, in the following description, in a case where it is not necessary to distinguish the second electrode layer 30 from the first electrode layer 28, both members are collectively referred to as an electrode layer.

In the piezoelectric film, a material for forming the electrode layer is not limited and various conductors can be used as the material. Specific examples thereof include conductive polymers such as carbon, palladium, iron, tin, aluminum, nickel, platinum, gold, silver, copper, chromium, molybdenum, alloys thereof, indium tin oxide, and polyethylene dioxythiophene-polystyrene sulfonic acid (PEDOT/PPS).

Among those, copper, aluminum, gold, silver, platinum, and indium tin oxide are suitably exemplified. Among these, from the viewpoints of conductivity, cost, and flexibility, copper is preferable.

In addition, a method of forming the electrode layer is not limited, and various known methods, for example, a film forming method such as a vapor-phase deposition method (a vacuum film forming method) such as vacuum vapor deposition and sputtering, a film forming method using plating, a method of affixing a foil formed of the materials described above, and a coating method can be used.

Among these, particularly from the viewpoint of ensuring the flexibility of the piezoelectric film 24, a thin film made of copper, aluminum, or the like formed by vacuum vapor deposition is suitably used as the electrode layer. Among these, in particular, a thin film made of copper formed by vacuum vapor deposition is suitably used.

The thickness of the first electrode layer 28 and the thickness of the second electrode layer 30 are not limited. In addition, the thicknesses of the first electrode layer 28 and the thicknesses of the second electrode layer 30 may basically be the same as or different from each other.

Here, similarly to the protective layer described above, in a case where the rigidity of the electrode layer is extremely high, not only is the stretching and contraction of the piezoelectric layer 26 constrained, but also the flexibility is impaired. Therefore, it is advantageous that the thickness of the electrode layer is reduced in a case where the electric resistance is not excessively high.

It is suitable that a product of the thicknesses of the electrode layer of the piezoelectric film 24 and the Young's modulus thereof is less than a product of the thickness of the protective layer and the Young's modulus thereof since the flexibility is not considerably impaired.

For example, in a case of a combination consisting of the protective layer formed of PET (Young's modulus: approximately 6.2 GPa) and the electrode layer consisting of copper (Young's modulus: approximately 130 GPa), the thickness of the electrode layer is preferably 1.2 μm or less, more preferably 0.3 μm or less, and still more preferably 0.1 μm or less in a case of assuming that the thickness of the protective layer is 25 μm.

The piezoelectric film 24 has a configuration in which the piezoelectric layer 26 is interposed between the first electrode layer 28 and the second electrode layer 30, and the laminate is further interposed between the first protective layer 32 and the second protective layer 34.

In such a piezoelectric film 24, it is preferable that the maximal value at which the loss tangent tans at a frequency of 1 Hz according to dynamic viscoelasticity measurement is 0.1 or more is present at room temperature.

In this manner, even in a case where the piezoelectric film 24 is subjected to large bending deformation from the outside at a relatively slow vibration of less than or equal to a few Hz, it is possible to effectively diffuse the strain energy to the outside as heat, whereby it is possible to prevent a crack from being generated on the interface between the polymer matrix and the piezoelectric particles.

In the piezoelectric film 24, it is preferable that the storage elastic modulus (E′) at a frequency of 1 Hz according to the dynamic viscoelasticity measurement is 10 to 30 GPa at 0° C., and 1 to 10 GPa at 50° C.

In this manner, the piezoelectric film 24 may have large frequency dispersion in the storage elastic modulus (E′) at room temperature. That is, the piezoelectric film 24 is able to be rigid with respect to a vibration of 20 Hz to 20 kHz, and is able to be flexible with respect to a vibration of less than or equal to a few Hz.

In the piezoelectric film 24, it is preferable that the product of the thickness and the storage elastic modulus (E′) at a frequency of 1 Hz according to the dynamic viscoelasticity measurement is in a range of 1.0×10⁶ to 2.0×10⁶ N/m at 0° C. and in a range of 1.0'10⁵ to 1.0×10⁶ N/m at 50° C.

In this manner, the piezoelectric film 24 may have moderate rigidity and mechanical strength within a range not impairing the flexibility and the acoustic characteristics.

Furthermore, in the piezoelectric film 24, it is preferable that the loss tangent tans at a frequency of 1 kHz at 25° C. is 0.05 or more in a master curve obtained from the dynamic viscoelasticity measurement.

Next, an example of the method for producing the piezoelectric film 24 will be described with reference to FIGS. 3 to 5.

First, a laminate 42b in which the second electrode layer 30 is formed on a surface of the second protective layer 34, as conceptually shown in FIG. 3, is prepared. Furthermore, a laminate 42a in which the first electrode layer 28 is formed on a surface of the first protective layer 32, as conceptually shown in FIG. 5, is prepared.

The laminate 42b may be manufactured by forming a copper thin film or the like as the second electrode layer 30 on a surface of the second protective layer 34 by vacuum vapor deposition, sputtering, plating, or the like. Similarly, the laminate 42a may be manufactured by forming a copper thin film or the like as the first electrode layer 28 on a surface of the first protective layer 32 by vacuum vapor deposition, sputtering, plating, or the like.

Alternatively, a commercially available sheet-like material in which a copper thin film or the like is formed on a protective layer may be used as the laminate 42b and/or the laminate 42a.

The laminate 42b and the laminate 42a may be the same as or different from each other.

Furthermore, in a case where, for example, the protective layer is extremely thin and the handleability is poor, a protective layer with a separator (temporary support) may be used, as necessary. Moreover, a PET having a thickness of 25 μm to 100 μm or the like can be used as the separator. The separator may be removed after thermal compression bonding of the electrode layer and the protective layer.

Next, as conceptually shown in FIG. 4, a piezoelectric layer 26 is formed on the second electrode layer 30 of the laminate 42b to manufacture a piezoelectric laminate 46 in which the laminate 42b and the piezoelectric layer 26 are laminated.

The piezoelectric layer 26 may be formed by a known method according to the piezoelectric layer 26.

For example, in a case of the piezoelectric layer (polymer-based piezoelectric composite layer) in which the piezoelectric particles 40 are dispersed in the polymer matrix 38 shown in FIG. 2, the piezoelectric layer is manufactured as follows by way of an example.

First, the coating material is prepared by dissolving the above-mentioned polymer material such as cyanoethylated PVA in an organic solvent, adding the piezoelectric particles 40 such as PZT particles thereto, and stirring the solution. The organic solvent is not limited, and various organic solvents such as dimethylformamide (DMF), methyl ethyl ketone, and cyclohexanone can be used.

In a case where the laminate 42b is prepared and the coating material is prepared, the coating material is cast (applied) onto the laminate 42b, and the organic solvent is evaporated and dried. In this manner, a piezoelectric laminate 46 having a second electrode layer 30 on the second protective layer 34, and having the piezoelectric layer 26 laminated on the second electrode layer 30, as shown in FIG. 4, is manufactured.

A casting method of the coating material is not limited, and any of known methods (coating devices) such as a bar coater, a slide coater, and a doctor knife is available.

Alternatively, in a case where the polymer material is a material that can be heated and melted, the piezoelectric laminate 46 as shown in FIG. 5 may be manufactured by heating and melting the polymer material to prepare a melt obtained by adding the piezoelectric particles 40 to the melted material, extruding the melt on the laminate 42b shown in FIG. 3 in a sheet shape by carrying out extrusion molding or the like, and cooling the laminate.

Furthermore, as described above, in the piezoelectric film 24, a polymer-based piezoelectric material such as PVDF may be added to the polymer matrix 38 in addition to the polymer material having a viscoelasticity at room temperature.

In a case where the polymer-based piezoelectric material is added to the polymer matrix 38, the polymer-based piezoelectric material to be added to the coating material may be dissolved. Alternatively, the polymer-based piezoelectric material to be added may be added to the heated and melted polymer material having a viscoelasticity at room temperature so that the polymer-based piezoelectric material is heated and melted.

After forming the piezoelectric layer 26, a calendaring treatment may be performed, as necessary. A calendaring treatment may be performed once or multiple times.

As is well known, the calendaring treatment is a treatment in which the surface to be treated is pressed while being heated by a heating press, a heating roller, and the like to flatten the surface.

In addition, the piezoelectric layer 26 of the piezoelectric laminate 46 having the second electrode layer 30 on the second protective layer 34 and the piezoelectric layer 26 formed on the second electrode layer 30 is subjected to a polarization treatment (poling).

A method of performing a polarization treatment on the piezoelectric layer 26 is not limited, and a known method can be used. Examples of the method include electric field poling in which a DC electric field is directly applied to a target to be subjected to the polarization treatment. Furthermore, in a case of performing the electric field poling, the first electrode layer 28 may be formed before the polarization treatment, and the electric field poling treatment may be performed using the first electrode layer 28 and the second electrode layer 30.

In addition, in a case where the piezoelectric film 24 is produced, in the polarization treatment, the polarization is performed in the thickness direction of the piezoelectric layer 26, not in the plane direction.

Next, as conceptually shown in FIG. 5, the laminate 42a which has been prepared in advance is laminated on the piezoelectric layer 26 side of the piezoelectric laminate 46 such that the first electrode layer 28 is directed toward the piezoelectric layer 26.

Furthermore, the laminate is subjected to thermal compression bonding using a heating press device, heating rollers, or the like such that the laminate is interposed between the first protective layer 32 and the second protective layer 34, thereby bonding the piezoelectric laminate 46 and the laminate 42a.

In this manner, the piezoelectric film 24 consisting of the piezoelectric layer 26, the first electrode layer 28 and the second electrode layer 30 provided on both surfaces of the piezoelectric layer 26, and the first protective layer 32 and the second protective layer 34 formed on a surface of the electrode layer is manufactured.

The piezoelectric film 24 which is manufactured by performing such a manufacturing step is polarized in the thickness direction instead of the plane direction, and thus, excellent piezoelectric characteristics are obtained even in a case where the stretching treatment is not performed after the polarization treatment. Therefore, the piezoelectric film 24 has no in-plane anisotropy as a piezoelectric characteristic, and stretches and contracts isotropically in all directions in the plane direction in a case where a driving voltage is applied.

As mentioned above, the piezoelectric element 14 in the example illustrated in the figure has five layers of the piezoelectric film laminated by folding the piezoelectric film 24 four times. In addition, the adjacent layers of the piezoelectric film 24 by the lamination are affixed to each other by the affixing layer 27 in a preferred aspect.

In the present invention, as the affixing layer 27, various known affixing agents (affixing materials) can be used as long as the adjacent layers of the piezoelectric film 24 can be affixed.

Therefore, the affixing layer 27 may be a layer consisting of an adhesive, a layer consisting of a pressure sensitive adhesive, or a layer consisting of a material having characteristics of both an adhesive and a pressure sensitive adhesive. An adhesive (adhesive material) is an affixing agent which has fluidity upon affixing and then turns into a solid. On the other hand, the pressure sensitive adhesive (adhesive material) is an affixing agent which is a gel-like (rubber-like) soft solid upon affixing, with the gel-like state not changing even after that.

In addition, the affixing layer 27 may be formed by applying an affixing agent having fluidity such as a liquid, or may also be formed by using a sheet-like affixing agent.

Here, for example, the piezoelectric element 14 is an exciter, and the piezoelectric element 14 is stretched and contracted by stretching and contracting the plurality of the laminated layers of the piezoelectric film 24, thereby vibrating the diaphragm 12 which will be described later to generate a sound. Accordingly, in the piezoelectric element 14, it is preferable that the stretching and contraction of each piezoelectric film 24 is directly transmitted. In a case where a substance having a viscosity to relieve vibration is present between the layers of the piezoelectric film 24, the efficiency of transmitting the stretching and contracting energy of the piezoelectric film 24 is lowered, and thus, the driving efficiency of the piezoelectric element 14 decreases.

In consideration of this point, the affixing layer 27 is preferably an adhesive layer consisting of an adhesive with which a solid and hard affixing layer 27 is obtained, rather than a pressure sensitive adhesive layer consisting of a pressure sensitive adhesive. Specific suitable examples of a more preferred affixing layer 27 include an affixing layer consisting of a thermoplastic type adhesive such as a polyester-based adhesive and a styrene-butadiene rubber (SBR)-based adhesive.

Adhesion, which is different from pressure sensitive adhesion, is useful in a case where a high adhesion temperature is required. In addition, the thermoplastic type adhesive has characteristics of “a relatively low temperature, a short time, and strong adhesion”, which is thus suitable.

In the piezoelectric element 14, the thickness of the affixing layer 27 is not limited, and a thickness capable of exhibiting sufficient affixing force may be appropriately set according to the forming material of the affixing layer 27.

Here, in the piezoelectric element 14, the thinner the affixing layer 27, the higher the effect of transmitting the stretching and contracting energy (vibration energy) of the piezoelectric layer 26, and the higher the energy efficiency. In addition, in a case where the affixing layer 27 is thick and has high rigidity, there is a possibility that the stretching and contraction of the piezoelectric film 24 may be constrained.

In consideration of this point, it is preferable that the affixing layer 27 is thinner than the piezoelectric layer 26. That is, it is preferable that the affixing layer 27 in the piezoelectric element 14 is hard and thin. Specifically, the thickness of the affixing layer 27 is preferably in a range of 0.1 to 50 μm, more preferably in a range of 0.1 to 30 μm, and still more preferably in a range of 0.1 to 10 μm in terms of thickness after affixing.

In the piezoelectric element 14 constituting the electroacoustic transducer 10 of the embodiment of the present invention, the affixing layer 27 is provided as a preferred embodiment and is not an essential constituent element.

Therefore, in a case where the piezoelectric element constituting the electroacoustic transducer 10 of the embodiment of the present invention has the layers of the piezoelectric film 24 laminated, the piezoelectric element may be configured by laminating and closely attaching the layers of the piezoelectric film 24 constituting the piezoelectric element using a known pressure bonding unit, a fastening unit, a fixing unit, or the like without having the affixing layer 27. For example, in a case where the piezoelectric film 24 is rectangular, the piezoelectric element may be configured by fastening four corners with members such as bolts and nuts, or the piezoelectric element may be configured by fastening four corners to a center portion with the same members. Alternatively, the piezoelectric element may be configured by laminating the layers of the piezoelectric film 24 and thereafter affixing the edge portion (edge surface) with a pressure sensitive adhesive tape to fix the laminated layers of the piezoelectric film 24.

However, in this case, in a case where a driving voltage is applied from the power source, the individual piezoelectric film 24 stretches and contracts independently, and in some cases, each layer of the piezoelectric film 24 bends in opposite directions and forms a void. As described above, in a case where the individual piezoelectric film 24 stretches and contracts independently, the driving efficiency of the piezoelectric element decreases, the degree of stretching and contraction of the entire laminated piezoelectric element decreases, and there is a possibility that an abutting diaphragm or the like cannot be sufficiently vibrated. In particular, in a case where the layers of the piezoelectric film 24 bend in the opposite directions and form a void, the driving efficiency of the piezoelectric element greatly decreases.

In consideration of this point, in a case where the piezoelectric element constituting the electroacoustic transducer of the embodiment of the present invention is configured by laminating a plurality of layers of the piezoelectric film 24, the piezoelectric element preferably has an affixing layer 27 that affixes the adjacent layers of the piezoelectric film 24 to each other by the piezoelectric element 14 in the example illustrated in the figure.

Moreover, in the electroacoustic transducer of the embodiment of the present invention, the piezoelectric element is not limited to one having a plurality of layers of the piezoelectric film 24 laminated by folding the piezoelectric film 24.

For example, the piezoelectric element may be one in which a plurality of cut sheet-like piezoelectric films 24 are laminated, and preferably, the adjacent piezoelectric films are affixed to each other by the affixing layer 27. At this time, the number of laminated layers is not limited, which is the same as that of the piezoelectric element 14 in which layers of the piezoelectric film 24 are laminated by folding the piezoelectric film 24. In addition, in a case where a plurality of cut sheet-like piezoelectric films 24 are laminated to form a piezoelectric element, a configuration in which different piezoelectric films are laminated to form a piezoelectric element, such as a configuration in which a piezoelectric film 24 having a protective layer and a piezoelectric film having no protective layer are laminated, may be used.

Alternatively, the piezoelectric element may be one composed of one sheet of the piezoelectric film 24 as long as a sufficient stretching and contracting force can be obtained for vibration of the diaphragm 12.

In the electroacoustic transducer 10 shown in FIG. 1, the piezoelectric element 14 has a plurality of layers of piezoelectric films laminated by folding the piezoelectric film 24. In such a piezoelectric element 14, the electrode layers facing each other in the adjacent layers of the piezoelectric film have the same polarity, and thus, even in a case where the electrode layers come into contact with each other, a short circuit does not occur. In addition, since the piezoelectric film 24 shown in FIG. 2 has a protective layer, basically, the electrode layers of adjacent piezoelectric films do not come into direct contact with each other.

Moreover, in a case where the cut sheet-like piezoelectric films 24 are laminated, since the piezoelectric film 24 shown in FIG. 2 has a protective layer, the protective layer acts as an insulating layer and a contact between the electrode layers, that is, a short circuit can be prevented even with the electrode layers facing each other.

In addition, in a case where the piezoelectric film has no protective layer, insulation between adjacent piezoelectric films may be achieved by various methods such as a method of providing an insulating layer between laminated piezoelectric films and a method of forming an affixing layer 27 with an insulating material.

A first extraction wiring line 24a and a second extraction wiring line 24b for electrically connecting to an external device such as a power supply device are connected to the piezoelectric film 24 of the piezoelectric element 14. The first extraction wiring line 24a is a wiring electrically extracted from the first electrode layer 28, and the second extraction wiring line 24b is a wiring line electrically extracted from the second electrode layer 30. In the following description, in a case where it is not necessary to distinguish between the first extraction wiring line 24a and the second extraction wiring line 24b, the both extraction wiring lines are also simply referred to as an extraction wiring line.

In the electroacoustic transducer 10 of the embodiment of the present invention, the connection method between the electrode layer and the extraction wiring line, that is, the extraction method is not limited, and various methods can be used.

Examples of the connection method include a method in which a through-hole is formed in a protective layer, an electrode connecting member formed of a metal paste such as a silver paste is provided so as to fill the through-hole, and an extraction wiring line is provided in the electrode connecting member. Other examples of the connection method include a method in which a rod-like or sheet-like extraction electrode is provided between an electrode layer and a piezoelectric layer, or between an electrode layer and a protective layer, and an extraction wiring line is connected to the extraction electrode. Alternatively, the extraction wiring line may be inserted directly between the electrode layer and the piezoelectric layer, or between the electrode layer and the protective layer, and the extraction wiring line may be connected to the electrode layer. Still other examples of the connection method include a method in which a part of the protective layer and an electrode layer is projected from a piezoelectric layer in the plane direction, and an extraction wiring line is connected to the projecting electrode layer. Furthermore, the extraction wiring line and the electrode layer may be connected by a known method such as a method using a metal paste such as a silver paste, a method using a solder, and a method using a conductive adhesive.

Suitable examples of the method for extracting an electrode, the method described in JP2014-209724A include the method described in JP2016-015354A.

Such a piezoelectric element 14 is accommodated and sealed in a sealing member 16 which has a gas barrier property and can be unsealed and closed after unsealing.

The sealing member 16 is, for example, a bag or a housing (box) formed of a sheet-like material having a gas barrier property. The sealing member 16 has no opening, or has an opening that can be opened and air-tightly closed by a lid, a zipper, or the like.

The sheet-like material that forms the sealing member 16 is not limited, and any sheet-like material consisting of various materials can be used as long as it has a gas barrier property that can prevent deterioration of the piezoelectric element 14 (piezoelectric film 24) due to humidity.

Examples of the sheet-like material include various resin films used as a gas barrier film, a sheet-like material obtained by depositing a metal thin film on a resin film, and a sheet-like material formed by forming an oxide film on a resin film.

The gas barrier property of the sheet-like material that forms the sealing member 16 is not limited as long as it can prevent deterioration of the piezoelectric element 14 due to humidity.

The sheet-like material that forms the sealing member 16 has a water vapor transmission rate (moisture permeability) of preferably 5 g/(m²·day) or less, more preferably 0.1 g/(m²·day) or less, still more preferably 0.01 g/(m²·day) or less, and particularly preferably 0.005 g/(m²·day) or less in an environment of 40° C. and 90% RH measured in accordance with JIS K7129B (MOCON method).

By setting the water vapor transmission rate of the sheet-like material that forms the sealing member 16 to 5 g/(m²·day) or less, deterioration of the piezoelectric element 14 due to humidity can be suitably prevented.

Basically, the lower the water vapor transmission rate of the sheet-like material that forms the sealing member 16, the more preferable it is, and there is no lower limit However, in consideration of the cost of the sealing member 16, the water vapor transmission rate of the sheet-like material that forms the sealing member 16 is preferably 0.1×10⁻⁶ g/(m²·day) or more.

The sealing member 16 seals the piezoelectric element 14 and is unsealable and closable after unsealing.

In the sealing member 16, the method of unsealing and closing after unsealing is not limited, and various known methods can be used.

Examples of the method include a method in which a sealing member 16 is formed of a heat-meltable material, and is thus unsealable by cutting using a cutter or the like, and then closed by heat-welding. Other examples of the method include a method of allowing a housing having an opening and the opening of the housing to be unsealed/closed by an air-tightly sealable lid. Still other examples of the method include a method of making it possible to unseal/close by a known air-tight zipper (a fastener, a chuck). Even still other examples of the method include adhesion by a heat sealing material.

Furthermore, the first extraction wiring line 24a and the second extraction wiring line 24b are inserted through the sealing member 16 while maintaining an air-tight state by a known method such as a method using a sealing material.

A thickness of the sheet-like material that forms the sealing member 16 is not limited, and the thickness may be appropriately selected so as to exhibit a sufficient gas barrier property according to the forming material.

Here, for the same reason as the affixing layer 18 and the like which will be described later, the sheet-like material that forms the sealing member 16 is preferably thin as long as necessary functions can be secured.

The thickness of the sheet-like material that forms the sealing member 16 is preferably 0.1 to 50 μm, more preferably 1 to 20 μm, and still more preferably 5 to 15 μm.

As shown in FIG. 1, the sealing member 16 is affixed to one principal surface of the diaphragm 12 by the affixing layer 18. Furthermore, the “principal surface” is the largest surface of a sheet-like material.

In addition, the piezoelectric element 14 is affixed to the inside of the sealing member 16 by the affixing layer 20 at a position facing the diaphragm 12.

In the present invention, as the affixing layer 18, various known affixing layers can be used as long as the diaphragm 12 and the sealing member 16 can be affixed to each other. In addition, as the affixing layer 20, various known affixing layers can be used as long as the sealing member 16 and the piezoelectric element 14 (piezoelectric film 24) can be affixed to each other.

Accordingly, the affixing layer 18 and the affixing layer 20 may each be a layer consisting of an adhesive, a layer consisting of a pressure sensitive adhesive, or a layer consisting of a material having characteristics of both an adhesive and a pressure sensitive adhesive, which are described above. In addition, the affixing layer 18 and the affixing layer 20 may be formed by applying an affixing agent having fluidity such as a liquid, or may be formed by using a sheet-like affixing agent.

Here, in the electroacoustic transducer 10 of the embodiment of the present invention, the piezoelectric element 14 is stretched and contracted by stretching and contracting a plurality of laminated layers of the piezoelectric film 24, and the diaphragm 12 is bent and vibrated by the stretching and contraction of the piezoelectric element 14, thereby producing a sound. Accordingly, in the electroacoustic transducer 10 of the embodiment of the present invention, it is preferable that the stretching and contraction of the piezoelectric element 14 is directly transmitted to the diaphragm 12. In a case where a substance having a viscosity that relieves vibration is present between the diaphragm 12 and the piezoelectric element 14, the efficiency of transmitting the stretching and contracting energy of the piezoelectric element 14 to the diaphragm 12 is lowered, and thus, the driving efficiency of the electroacoustic transducer 10 decreases.

In consideration of this point, the affixing layer 18 and the affixing layer 20 are each preferably an adhesive layer consisting of an adhesive, with which an affixing layer 18 and an affixing layer 20 that are solid and hard are obtained, rather than a pressure sensitive adhesive layer consisting of a pressure sensitive adhesive. Specific suitable examples of the affixing layer 18 and the affixing layer 20 which are more preferable include an affixing layer consisting of a thermoplastic type adhesive such as a polyester-based adhesive and a styrene-butadiene rubber (SBR)-based adhesive.

Adhesion, which is different from pressure sensitive adhesion, is useful in a case where a high adhesion temperature is required. In addition, the thermoplastic type adhesive has characteristics of “a relatively low temperature, a short time, and strong adhesion”, which is thus suitable.

In the electroacoustic transducer 10 of the embodiment of the present invention, the thickness of the affixing layer 18 and the thickness of the affixing layer 20 are not limited, and a thickness capable of exhibiting a sufficient affixing force may be appropriately set according to a material for forming the affixing layer 27.

Here, in the electroacoustic transducer 10 in the example illustrated in the figure, the thinner the affixing layer 18 and the affixing layer 20, the higher the effect of transmitting the stretching and contracting energy (vibration energy) of the piezoelectric layer 26, and the higher the energy efficiency. In addition, in a case where the affixing layer 18 and the affixing layer 20 are thick and have high rigidity, there is also a possibility that the stretching and contraction of the piezoelectric element 14 may be constrained.

In consideration of this point, it is preferable that the affixing layer 18 and the affixing layer 20 are thin.

Specifically, the thickness of the affixing layer 18 is preferably 10 to 1,000 μm, more preferably 30 to 500 μm, and still more preferably 50 to 300 μm. On the other hand, the thickness of the affixing layer 20 is preferably 10 to 1,000 μm, more preferably 30 to 500 μm, and still more preferably 50 to 300 μm. Furthermore, the thicknesses of the affixing layer 18 and the affixing layer 20 are both a thickness after affixing.

In the electroacoustic transducer 10 of the embodiment of the present invention, the affixing layer 18 permanently affixes the diaphragm 12 and the sealing member 16 to each other. That is, in the electroacoustic transducer 10, basically, the diaphragm 12 and the sealing member 16 are not peeled from each other.

On the other hand, as will be described later, for example, in a case where the piezoelectric element 14 is in failure or in a case where the piezoelectric element 14 cannot exhibit predetermined performance due to deterioration, it is peeled and taken out from the sealing member 16. Thereafter, as will be described later, an appropriate piezoelectric element 14 is inserted into the sealing member 16 and affixed by the affixing layer 20.

Furthermore, at this time, the piezoelectric element 14 may be peeled together with the affixing layer 20, or the affixing layer 20 may be left on the sealing member 16 and only the piezoelectric element 14 may be peeled. However, from the viewpoint that the affixing layer 20 is sufficiently thin and a sufficient affixing force can be obtained, it is preferable that the piezoelectric element 14 is peeled and affixed together with the affixing layer 20. That is, in the electroacoustic transducer 10, it is preferable to replace the piezoelectric element 14 with a new one at the same time as replacing the affixing layer 20.

Accordingly, in the electroacoustic transducer 10 of the embodiment of the present invention, it is preferable that the affixing force between the sealing member 16 and the piezoelectric element 14 is weaker than the affixing force between the diaphragm 12 and the sealing member 16.

That is, in the electroacoustic transducer 10 of the embodiment of the present invention, it is preferable that the affixing force by the affixing layer 20 is weaker than the affixing force by the affixing layer 18.

A method for making the affixing force between the sealing member 16 and the piezoelectric element 14 weaker than the affixing force between the diaphragm 12 and the sealing member 16 is not limited, and various known methods can be used.

By ways of an example, various known methods such as a method of selecting an adhesive to be used, a method of selecting a pressure sensitive adhesive to be used, a method of using an adhesive as the affixing layer 20 and a pressure sensitive adhesive as the affixing layer 18, and a method of adjusting the thickness of the affixing layer 18 and the thickness of the affixing layer 20 are available.

In addition, in the electroacoustic transducer 10 of the embodiment of the present invention, the sealing member 16 and the piezoelectric element 14 may be made peelable from each other while keeping the sealing member 16 affixed to the diaphragm 12 by using an affixing agent whose affixing force can be adjusted in the affixing layer 20.

Examples of the method include a method of using an affixing agent whose affixing force decreases by moisture absorption in the affixing layer 20. In this manner, the sealing member 16 and the piezoelectric element 14, and the diaphragm 12 and the sealing member 16 are usually affixed to each other with a sufficient affixing force. In a case of taking out the piezoelectric element 14, the sealing member 16 is opened and water is sprayed inside by spraying or the like to cause the affixing force of the affixing layer 20 to decrease. In this manner, the affixing force between the sealing member 16 and the piezoelectric element 14 is made weaker than the affixing force between the diaphragm 12 and the sealing member 16, and the piezoelectric element 14 is peeled from the sealing member 16.

Examples of the affixing agent whose affixing force decreases by moisture absorption include an emulsion-based affixing agent.

The affixing force between the sealing member 16 and the piezoelectric element 14 and the affixing force between the diaphragm 12 and the sealing member 16 are not limited. That is, the affixing force of the affixing layer 18 and the affixing layer 20 is not limited. In addition, a difference between the affixing force between the sealing member 16 and the piezoelectric element 14 and the affixing force between the diaphragm 12 and the sealing member 16 is also not limited. That is, a difference in the affixing force between the affixing layer 18 and the affixing layer 20 is also not limited.

In the electro acoustic transducer 10 of the embodiment of the present invention, the affixing force of the affixing layer 18 and the affixing layer 20 may be appropriately set such that the sealing member 16 and the diaphragm 12, and the sealing member 16 and the piezoelectric element 14 are affixed with a sufficient force to enable the vibration of the diaphragm 12 in the electroacoustic transducer 10, and the sealing member 16 and the piezoelectric element 14 can be peeled without making the diaphragm 12 and the sealing member 16 peeled.

In the electroacoustic transducer 10 in the example illustrated in the figure, the piezoelectric film 24 is formed by interposing the piezoelectric layer 26 between the first electrode layer 28 and the second electrode layer 30.

The piezoelectric layer 26 preferably has the piezoelectric particles 40 in the polymer matrix 38. Preferably, in the piezoelectric layer 26, the piezoelectric particles 40 are dispersed in the polymer matrix 38.

In a case where a voltage is applied to the second electrode layer 30 and the first electrode layer 28 of the piezoelectric film 24 having such a piezoelectric layer 26, the piezoelectric particles 36 stretch and contract in the polarization direction according to the applied voltage. As a result, the piezoelectric film 24 (piezoelectric layer 26) contracts in the thickness direction. At the same time, the piezoelectric film 24 stretches and contracts in the plane direction due to the Poisson's ratio.

The degree of stretching and contraction is approximately in a range of 0.01% to 0.1%.

As described above, a thickness of the piezoelectric layer 26 is preferably approximately 10 to 300 μm. Accordingly, the degree of stretching and contraction in the thickness direction is as extremely small as approximately 0.3 μm at most.

On the contrary, the piezoelectric film 24, that is, the piezoelectric layer 26, has a size much larger than the thickness in the plane direction. Accordingly, for example, in a case where the length of the piezoelectric film 24 is 20 cm, the piezoelectric film 24 stretches and contracts by about 0.2 mm at most by the application of a voltage.

As described above, the piezoelectric element 14 has five layers of the piezoelectric film 24 laminated by folding the piezoelectric film 24. In addition, the diaphragm 12 is affixed to the sealing member 16 by the affixing layer 18, and the piezoelectric element 14 is affixed to the sealing member 16 by the affixing layer 20.

The piezoelectric element 14 also stretches and contracts in the same direction by the stretching and contraction of the piezoelectric film 24. The stretching and contraction of the piezoelectric element 14 causes the diaphragm 12 to bend, and as a result, the diaphragm 12 vibrates in the thickness direction.

The diaphragm 12 generates a sound due to the vibration in the thickness direction. That is, the diaphragm 12 vibrates according to the magnitude of the voltage (driving voltage) applied to the piezoelectric film 24, and generates a sound according to the driving voltage applied to the piezoelectric film 24.

Here, it is known that in a case where a general piezoelectric film consisting of a polymer material such as PVDF is stretched in a uniaxial direction after being subjected to polarization treatment, the molecular chains are aligned with respect to the stretching direction, and as a result, high piezoelectric characteristics are obtained in the stretching direction. Therefore, a typical piezoelectric film has in-plane anisotropy as a piezoelectric characteristic and has anisotropy in the amount of stretch and contraction in the plane direction in a case where a voltage is applied.

On the contrary, in the electroacoustic transducer 10, since the piezoelectric film 24 consisting of a polymer-based piezoelectric composite material in which the piezoelectric particles 36 are dispersed in the polymer matrix 38 shown in FIG. 2 achieves high piezoelectric characteristics without stretching after the polarization treatment, the piezoelectric film 24 has no in-plane anisotropy in the piezoelectric characteristics, and stretches and contracts isotropically in all directions in the plane direction. That is, in the electroacoustic transducer 10 in the example illustrated in the figure, the piezoelectric film 24 shown in FIG. 2, constituting the piezoelectric element 14, stretches and contracts isotropically and two-dimensionally. According to the piezoelectric element 14 in which layers of such a piezoelectric film 24 that stretch and contract isotropically and two-dimensionally are laminated, compared to a case where layers of general piezoelectric films such as PVDF, which stretch and contract greatly in only one direction, are laminated, the diaphragm 12 can be vibrated with a large force. As a result, according to the piezoelectric element 14 in which layers of the piezoelectric film 24 stretching and contracting isotropically two-dimensionally are laminated, a larger and more beautiful sound can be generated.

As described above, the piezoelectric element 14 in the example illustrated in the figure has five layers of such a piezoelectric film 24 laminated. In the piezoelectric element 14 in the example illustrated in the figure, as a preferable embodiment, the layers of the piezoelectric film 24 adjacent to each other are further affixed by the affixing layer 27.

Therefore, even though the rigidity of each piezoelectric film 24 is low and the stretching and contracting force thereof is small, the rigidity is increased by laminating the layers of the piezoelectric film 24, and the stretching and contracting force as the piezoelectric element 14 is increased. As a result, in the piezoelectric element 14, even in a case where the diaphragm 12 has a certain degree of rigidity, the diaphragm 12 is sufficiently bent with a large force and the diaphragm 12 can be sufficiently vibrated in the thickness direction, whereby the diaphragm 12 can generate a sound.

In addition, in a case where the thickness of the piezoelectric layer 26 increases, the stretching and contracting force of the piezoelectric film 24 increases, but the driving voltage required for stretching and contracting the film is increased by the same amount. Here, in the piezoelectric element 14, since the preferred thickness of the piezoelectric layer 26 is approximately 300 μm at most as described above, the piezoelectric film 24 can be sufficiently stretched and contracted even in a case where the voltage applied to each piezoelectric film 24 is small.

Here, in the electroacoustic transducer 10 of the embodiment of the present invention, the piezoelectric element 14 is sealed in a sealing member 16 having a gas barrier property.

Therefore, even in a case where the piezoelectric film 24 constituting the piezoelectric element 14 is deteriorated by moisture absorption, deterioration of the piezoelectric element 14 caused by moisture absorption can be prevented. Accordingly, the electroacoustic transducer 10 of the embodiment of the present invention can operate stably for a long period of time by preventing deterioration caused by moisture absorption.

However, in the electroacoustic transducer 10, the piezoelectric element 14 is deteriorated and in failure due to various factors with use and succession. For example, even in a case where the sealing member 16 is sealed, the piezoelectric film 24 constituting the piezoelectric element 14 may be deteriorated by moisture absorption, depending on the usage environment and the like of the electroacoustic transducer 10.

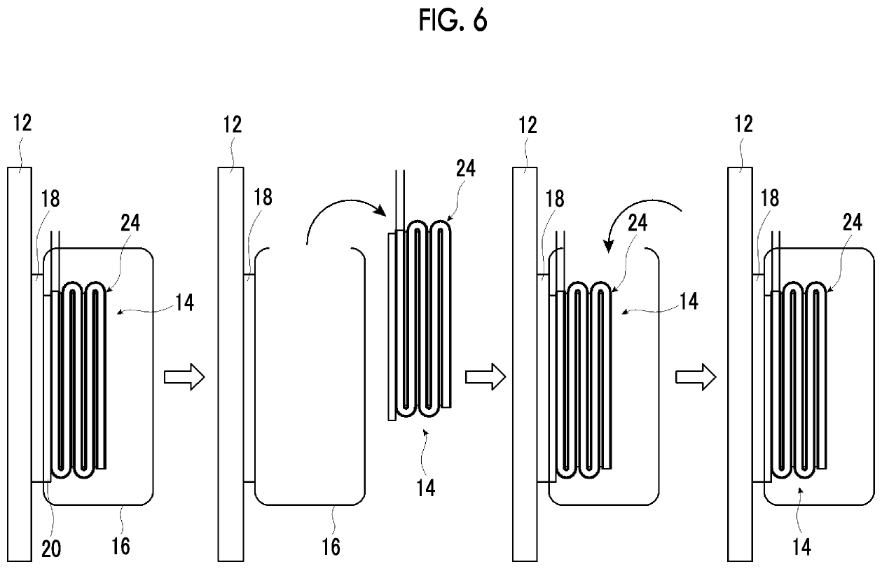

At this time, in the electroacoustic transducer 10 of the embodiment of the present invention, replacement of the piezoelectric element 14 can be performed. Hereinafter, description will be made with reference to a conceptual view of FIG. 6.

In a case where the piezoelectric element 14 is deteriorated, in the electroacoustic transducer 10, the sealing member 16 that seals the piezoelectric element 14 is opened, as conceptually shown on the left side and the second from the left in FIG. 6, and the piezoelectric element 14 and the affixing layer 20 are peeled from the sealing member 16 and taken out from the sealing member 16.

The sealing member 16 may be unsealed by the known method described above. By way of an example, the sealing member 16 is cut by a cutter knife or scissors and opened, and the piezoelectric element 14 and the affixing layer 20 are peeled from the sealing member 16 and taken out.

In addition, for example, in a case where the affixing layer 20 consists of an affixing agent whose affixing force decreases by moisture absorption, the inside of the sealing member 16 is humidified by spraying or the like to cause the affixing force of the affixing layer 20 to decrease, and the piezoelectric element 14 is peeled from the sealing member 16.

Next, as shown third from the left in FIG. 6, the affixing layer 20 is affixed to a new (appropriate) piezoelectric element 14 and accommodated in the sealing member 16. Furthermore, the piezoelectric element 14 is affixed to the sealing member 16 at a position facing the diaphragm 12 by the affixing layer 20.

After the piezoelectric element 14 is affixed to the sealing member 16, the piezoelectric element 14 is sealed in the sealing member 16 by reclosing the unsealed portion of the sealing member 16, as shown on the right side of FIG. 6. The sealing member 16 may be reclosed by the known method described above. By way of an example, in a case where the sealing member 16 is formed of a heat-meltable material and the sealing member 16 is cut by a cutter knife and opened, the cut portion of the sealing member 16 is heat-welded to close the unsealed sealing member 16, the piezoelectric element 14 is sealed in the sealing member 16.

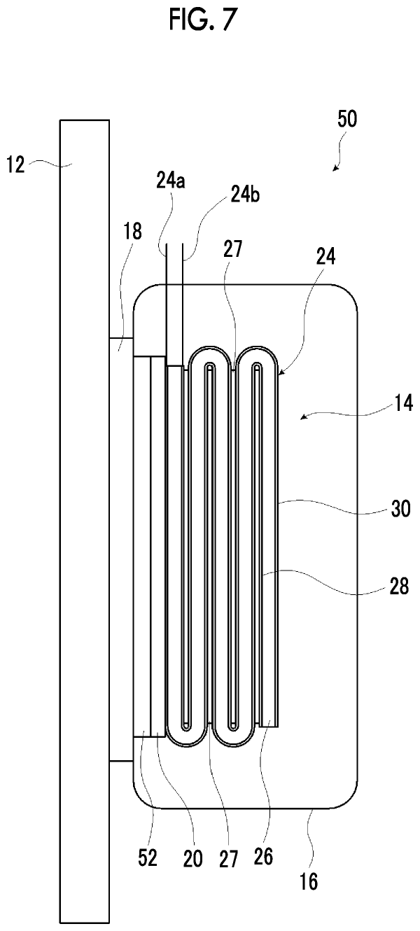

FIG. 7 conceptually shows another example of the electroacoustic transducer of the embodiment of the present invention.

Furthermore, in the electroacoustic transducer 50 shown in FIG. 7, since the same members as those of the electroacoustic transducer 10 shown in FIG. 1 and the like are widely used, the same members are designated by the same reference numerals and different members will be mainly described.

The electroacoustic transducer 50 shown in FIG. 7 has an affixing part 52 for affixing the affixing layer 20, that is, the piezoelectric element 14 to the inside of the sealing member 16.

By incorporation of such an affixing part 52, the fixed position of the piezoelectric element 14 in the sealing member 16 can be stabilized. In addition, since the affixing part 52 is a member provided for affixation of the affixing layer 20, affixation of the affixing layer 20 to the sealing member 16, that is, affixation of the piezoelectric element 14 can be stabilized by incorporation of the affixing part 52.

Furthermore, by increasing the surface roughness of a surface of the affixing part 52 affixed to the affixing layer 20, the affixing force between the sealing member 16 and the piezoelectric element 14 can be made weaker than the affixing force between the diaphragm 12 and the sealing member 16 even in a case where the same affixing agent as for the affixing layer 18 and the affixing layer 20 is used.

The material for forming the affixing part 52 is not limited, and a sheet-like material consisting of various known materials can be used.

Examples of the material for forming the affixing part 52 include resin materials such as a silicone-based resin adhesive and an acrylic resin adhesive.

A thickness of the affixing part 52 is not limited. However, for the same reason as with the affixing layer 18, it is preferable that the affixing part 52 is thin as long as it can exhibit its function.

The thickness of the affixing part 52 is preferably 5 to 1,000 μm, more preferably 20 to 700 μm, and still more preferably 50 to 500 μm.

A size of the affixing part 52 may be appropriately set according to the size of the piezoelectric element 14 to be affixed inside the sealing member 16.

In the electroacoustic transducer of the embodiment of the present invention, the number of piezoelectric elements 14 affixed to one diaphragm 12 may be one or a plurality. The number of piezoelectric elements 14 to be affixed to one diaphragm 12 is not limited, and may be appropriately set according to the type of the diaphragm 12, the application of the diaphragm 12, the size of the diaphragm 12, and the like.

In addition, a position where the sealing member 16, that is, the piezoelectric element 14 is affixed to the diaphragm 12 is not limited, and may be appropriately set according to the type of the diaphragm 12, the application of the diaphragm 12, the size of the diaphragm 12, and the like.

Furthermore, in the electroacoustic transducer of the embodiment of the present invention, a plurality of piezoelectric elements 14 may be affixed in one sealing member 16.

While the electroacoustic transducer of the embodiment of the present invention has been described in detail, the present invention is not limited to the above-mentioned examples, and various improvements or modifications may be naturally performed within a range not deviating from the gist of the present invention.

The electroacoustic transducer can be suitably used as a speaker in various applications.

### Explanation of References

10, 50: electroacoustic transducer

12: diaphragm

14: piezoelectric element

16: sealing member

18, 20, 27: affixing layer

24: piezoelectric film

24a: first extraction wiring line

24b: second extraction wiring line

26: piezoelectric layer

28: first electrode layer

30: second electrode layer

32: first protective layer

34: second protective layer

38: polymer matrix

40: piezoelectric particles

42a, 42b: laminate

46 piezoelectric laminate

52: affixing part

What is claimed is:

1. An electroacoustic transducer comprising:
a diaphragm;
a sealing member affixed to one principal surface of the diaphragm, the sealing member having a gas barrier property and being unsealable and closable after unsealing; and
a piezoelectric element sealed in the sealing member and affixed to face the diaphragm in the sealing member, the piezoelectric element using a piezoelectric film provided with electrode layers on both surfaces of a piezoelectric layer.

2. The electroacoustic transducer according to claim 1,
wherein an affixing force between the sealing member and the piezoelectric element is weaker than an affixing force between the diaphragm and the sealing member, or
the affixing force between the sealing member and the piezoelectric element is set to be weaker than the affixing force between the diaphragm and the sealing member.

3. The electroacoustic transducer according to claim 1,
wherein an affixing agent that affixes the piezoelectric element and the sealing member to each other has an affixing force that decreases by moisture absorption.

4. The electroacoustic transducer according to claim 1,
wherein the piezoelectric element has a plurality of layers of the piezoelectric film laminated.

5. The electroacoustic transducer according to claim 4,
wherein the piezoelectric element has the plurality of layers of the piezoelectric film laminated by folding the piezoelectric film one or more times.

6. The electroacoustic transducer according to claim 1,
wherein the sealing member is closable by heat-welding after unsealing.

7. The electroacoustic transducer according to claim 1,
wherein the piezoelectric layer of the piezoelectric film is a polymer-based piezoelectric composite material having piezoelectric particles in a polymer material.

8. The electroacoustic transducer according to claim 7,
wherein the polymer material has a cyanoethyl group.

9. The electroacoustic transducer according to claim 8,
wherein the polymer material is cyanoethylated polyvinyl alcohol.

10. The electroacoustic transducer according to claim 1,
wherein the piezoelectric film has a protective layer on a surface of the electrode layer.

11. The electroacoustic transducer according to claim 2,
wherein an affixing agent that affixes the piezoelectric element and the sealing member to each other has an affixing force that decreases by moisture absorption.

12. The electroacoustic transducer according to claim 2,
wherein the piezoelectric element has a plurality of layers of the piezoelectric film laminated.

13. The electroacoustic transducer according to claim 12,
wherein the piezoelectric element has the plurality of layers of the piezoelectric film laminated by folding the piezoelectric film one or more times.

14. The electroacoustic transducer according to claim 2,
wherein the sealing member is closable by heat-welding after unsealing.

15. The electroacoustic transducer according to claim 2,
wherein the piezoelectric layer of the piezoelectric film is a polymer-based piezoelectric composite material having piezoelectric particles in a polymer material.

16. The electroacoustic transducer according to claim 15,
wherein the polymer material has a cyanoethyl group.

17. The electroacoustic transducer according to claim 16,
wherein the polymer material is cyanoethylated polyvinyl alcohol.

18. The electroacoustic transducer according to claim 2,
wherein the piezoelectric film has a protective layer on a surface of the electrode layer.

19. The electroacoustic transducer according to claim 3,
wherein the piezoelectric element has a plurality of layers of the piezoelectric film laminated.

20. The electroacoustic transducer according to claim 19,
wherein the piezoelectric element has the plurality of layers of the piezoelectric film laminated by folding the piezoelectric film one or more times.
